(19) United States
(12) Patent Application Publication
(10) Pub. No.: US 2026/0351900 A1
(43) Pub. Date: Nov. 5, 2026

(54) CAMERA ASSEMBLY

(71) Applicant: Hanwha Vision Co., Ltd., Seongnam-si (KR)

(72) Inventors: Jinhyuk CHOI, Seongnam-si (KR); ByeongHo LEE, Seongnam-si (KR); Changyeon KIM, Seongnam-si (KR); Hoseoung HWANG, Seongnam-si (KR); Dongwoo KIM, Seongnam-si (KR); WoonDo JUNG, Seongnam-si (KR)

(21) Appl. No.: 19/664,043

(22) Filed: Apr. 30, 2026

(30) Foreign Application Priority Data
May 2, 2025 (KR) 10-2025-0058179

(51) Int. Cl. H01R 13/635; G03B 17/56; H01R 13/621; H01R 13/629; H01R 13/631; H05K 5/02

(52) U.S. Cl. CPC H01R 13/635; G03B 17/561; H01R 13/6215; H01R 13/62977; H01R 13/631; H05K 5/0221; H01R 2201/04

(57) ABSTRACT

A camera assembly may include, for example, a bottom case configured to attach to an installation surface, a top case having a first side detachably coupled to the bottom case to form an accommodation space within the top case and the bottom case, a camera module mounted on a second side of the top case, and a connector carrier assembly including a power cable and a network cable. The connector carrier assembly may be configured to be movable between a stowed position and an ejected position. The power cable and the network cable of the connector carrier assembly may be configured to be: based on the connector carrier assembly being in the stowed position, connected to the camera module, and based on the connector carrier assembly being in the ejected position, disconnected from the camera module.

### CROSS-REFERENCE TO RELATED APPLICATION

This application claims priority from and the benefit of Korean Patent Application No. 10-2025-0058179, filed May 2, 2025 in the Korean Intellectual Property Office, the entire content of which is incorporated herein by reference.

### TECHNICAL FIELD

The present disclosure relates to a camera assembly, and more particularly, to a camera assembly that allows even a single operator to easily install a camera module.

### BACKGROUND

Surveillance cameras for monitoring a specific area may be provided with a plurality of camera modules having pan/tilt/zoom movements, for the purpose of covering a wide area with a small number of devices and tracking moving objects. In particular, among different types of surveillance cameras, a dome camera has a circularly symmetric shape about a central axis, and thus may facilitate pan/tilt/zoom movements and miniaturization. These characteristics have helped it gain wide adoption.

The dome camera may include a transparent dome cover that encloses a plurality of cameras. The dome camera may be configured to prevent fogging or condensation of the dome cover by directing air toward an inner surface of the dome cover using a fan mounted inside the dome cover. For example, some implementations of dome cameras may be provided with a plurality of blowing fans corresponding to positions near a plurality of camera modules arranged in a circumferential direction of a housing, and a plurality of intake ports and exhaust ports.

The blowing fans may be used to remove moisture generated due to a temperature difference between inside and outside of the camera, or may be used to cool a camera module or a circuit board that may be overheated depending on an installation or use environment.

However, in such implementations of camera assemblies, when a retention force on a rotating part is released in order to adjust an operating range of a camera module mounted on a housing fixed to an installation surface, a problem may arise whereby the rotating part may become detached from the housing or may be freely rotated due to the camera module’s own weight. This may significantly compromise structural integrity of the camera assembly.

The matters described in this Background section are only for enhancement of understanding of the background of the disclosure, and should not be taken as acknowledgement that they correspond to prior art already known to those skilled in the art.

### SUMMARY

The present disclosure has been made to solve the above problems, and an object thereof is to provide a camera assembly that allows even a single operator to easily install a camera module.

The objectives of the present disclosure are not limited to those mentioned above, and other objectives not explicitly stated will be clearly understood by those skilled in the art based on the following description.

According to one or more example embodiments of the present disclosure, a camera assembly may include: a bottom case configured to attach to an installation surface; a top case having a first side detachably coupled to the bottom case to form an accommodation space within the top case and the bottom case; a camera module mounted on a second side of the top case; and a connector carrier assembly including a power cable and a network cable. The connector carrier assembly may be configured to be movable, through an opening formed on a side surface of at least one of the bottom case or the top case, between a stowed position, in which the connector carrier assembly is disposed in the accommodation space, and an ejected position, in which the connector carrier assembly is at least partially ejected from the accommodation space. The power cable and the network cable of the connector carrier assembly may be configured to be: based on the connector carrier assembly being in the stowed position, connected to the camera module; and, based on the connector carrier assembly being in the ejected position, disconnected from the camera module.

The connector carrier assembly may include: a movable frame disposed to be slidable on a guide rail installed on the bottom case; and a connector housing mounted on the movable frame and having a first connector connected to the power cable or the network cable provided on a first position of the connector housing. The connector housing may be configured to move the first connector to be connected to a second connector that is connected to the camera module.

The connector carrier assembly may further include a first spring connected between the movable frame and the guide rail and providing an elastic restoring force such that the movable frame is ejected outward from the accommodation space.

The connector carrier assembly may further include: a fastener provided on a second side of the connector housing and configured to lock the connector housing and the bottom case in the stowed position; and a second spring configured to push the fastener outward by a predetermined distance from the second side of the connector housing based on a retention force between the connector housing and the bottom case being released.

At a moment when the retention force of the fastener is released, connection between the first connector and the second connector may be released by the elastic restoring force of the first spring.

The top case may include: a rotation stop protruding from an upper surface to prevent rotation of the camera module; a lever disposed to be, according to entry or exit of the connector housing, rotatable inside the top case to push the rotation stop out of the top case or pull the rotation stop into the top case; an inner case provided to cover a lower portion of the rotation stop and the lever inside the top case; and a third spring configured to push the lever and the rotation stop from an inner bottom surface of the inner case such that the rotation stop protrudes from the upper surface of the top case.

The connector housing may include a cam that is configured to: cause the lever to rotate in a first direction, while the connector housing is being inserted into the accommodation space, to lower the rotation stop, and, based on the connector housing being ejected out of the accommodation space and a force for rotating the lever in the first direction being released, raise the rotation stop and the lever by the third spring to cause the rotation stop to protrude from the top case.

The power cable or the network cable may be connected through one inlet hole selected from among: a first inlet hole formed on a bottom surface of the bottom case facing the installation surface, and a second inlet hole formed on a side surface adjacent to the installation surface.

The top case may include a plurality of locking pins protruding toward the accommodation space. Each locking pin, of the plurality of locking pins, may have a head portion formed with a larger cross-sectional area at a protruding end than at an opposite end of the locking pin.

The bottom case may include a fastening frame installed in the accommodation space and configured to keep the top case fastened to the bottom case while the plurality of locking pins are inserted and rotated along a circumferential direction.

The fastening frame may include a plurality of keyhole slots. Each keyhole slot of the plurality of keyhole slots may include: an entry portion having a diameter such that the head portion of a corresponding locking pin, of the plurality of locking pins, is insertable through the entry portion; a retention portion having a width that is less than the diameter of the entry portion and communicating with the entry portion on a first side of the retention portion; and an inclined surface configured to change a coupling direction of the head portion, of the corresponding locking pin, inserted into the entry portion toward the retention portion, thereby securing a corresponding locking pin of the plurality of locking pins at the retention portion.

The connector carrier assembly may be configured to, based on the top case and the bottom case being coupled and each of the plurality of locking pins rotating to a second side of the retention portion of a corresponding keyhole slot, slide into the accommodation space.

The connector housing may include a shielding surface configured to, based on the connector housing being in the stowed position, have a same side surface structure as a side surface of the bottom case.

The connector housing may be configured to slide inward into the accommodation space, to be in the stowed position, such that the shielding surface and the side surface of the bottom case are flush with each other, and the first connector and the second connector are connected to each other.

The first connector and the second connector may be disposed in parallel with a sliding direction of the connector housing, such that power cable and the network cable are simultaneously connected to the camera module or disconnected from the camera module according to a sliding movement of the connector housing.

The first spring may be configured to: maintain a maximally stretched state based on the connector housing being in the stowed position, or, based on the retention force being released, push the connector housing to the ejected position and physically separate the first connector from the second connector.

Based on the connector carrier assembly being in the stowed position, rotation of the camera module on the top case may be enabled. Based on the connector carrier assembly being in the ejected position, rotation of the camera module on the top case may be restricted.

The second connector may be disposed at a fixed position inside the bottom case. The first connector may be fixed inside the connector housing, such that the first connector is inserted into or detached from the second connector as the connector housing slides along the guide rail.

The first spring may be configured to: store energy based on the connector housing being in the stowed position; and push the connector housing outward from the bottom case with a force greater than a coupling force between the first connector and the second connector based on the retention force of the fastener being released.

The sliding direction of the connector housing may be parallel to a direction in which the first connector is inserted into the second connector. Based on the connector housing being in the stowed position, the first connector may be fully inserted into the second connector.

### BRIEF DESCRIPTION OF THE DRAWINGS

The following detailed description of one or more example embodiments of the present application, as well as the above summary, will be better understood when read in connection with the accompanying drawings. The drawings illustrate the example embodiment(s) for the purpose of exemplifying the present disclosure. However, it should be understood that the present application is not limited to the exact arrangements and means shown.

FIG. 1 is a perspective view illustrating a camera assembly.

FIGS. 2 and 3 are reference views illustrating a case for mounting a camera module of the camera assembly illustrated in FIG. 1 on an installation surface.

FIG. 4 is a perspective view illustrating a state in which a bottom case of the camera assembly illustrated in FIG. 2 is installed on an installation surface.

FIG. 5 is a reference view illustrating a state in which power and network cables are connected inside the bottom case of the camera assembly illustrated in FIG. 4.

FIGS. 6 and 7 are perspective views illustrating a switching module of the camera assembly illustrated in FIG. 4.

FIG. 8 is a reference view illustrating a lower portion of a camera module and a top case of the camera assembly illustrated in FIG. 2.

FIGS. 9 and 10 are reference views illustrating a state in which the top case and the bottom case of the camera assembly illustrated in FIG. 4 are coupled.

FIGS. 11 and 12 are reference views illustrating a rotation prevention member of the camera assembly illustrated in FIG. 2.

FIGS. 13 and 14 are cross-sectional views illustrating an operating state of the rotation prevention member of the camera assembly illustrated in FIG. 11.

### DETAILED DESCRIPTION

Hereinafter, one or more example embodiments of the present disclosure will be described in detail with reference to the accompanying drawings. Advantages and features of the present disclosure, and methods for achieving the same, will become apparent with reference to example embodiment(s) described in detail below together with the accompanying drawings. However, the present disclosure is not limited to the example embodiment(s) disclosed below, but may be implemented in various different forms. The example embodiment(s) are provided only to convey the scope of the present disclosure to those of ordinary skill in the art, and the present disclosure is defined only by the scope of the claims. Throughout the specification, like reference numerals denote like elements.

The present disclosure may undergo various modifications and may have a number of embodiments, and one or more example embodiments will be illustrated and described in the drawings.

Terms including ordinals such as first, second, and the like may be used to describe various components, but the components are not limited by such terms.

Such terms are used only for the purpose of distinguishing one component from another.

For example, without departing from the scope of the present disclosure, a second component may be referred to as a first component, and similarly, the first component may be referred to as the second component.

For purposes of the present application and the claims, using the example phrase “at least one of: A; B; or C” or “at least one of A, B, or C,” the phrase means “at least one A, or at least one B, or at least one C, or any combination of at least one A, at least one B, and at least one C. Further, example phrases, such as "A, B, or C," "at least one of A, B, and C," "at least one of A, B, or C," etc. as used herein may mean each listed item or all possible combinations of the listed items. For example, "at least one of A or B" may refer to (1) at least one A; (2) at least one B; or (3) at least one A and at least one B.

The term “and/or” includes a combination of a plurality of related listed items or any one of the plurality of related listed items.

When a component is referred to as being “connected to” or “coupled to” another component, it may be directly connected to or coupled to the other component, but it should be understood that other components may be interposed therebetween.

In contrast, when a component is referred to as being “directly connected to” or “directly coupled to” another component, it should be understood that no other component is interposed therebetween.

The terms used in this application are merely for describing example embodiment(s) and are not intended to limit the present disclosure.

Unless clearly indicated otherwise by the context, singular expressions include plural expressions.

In this application, the terms “include” or “have,” and the like merely specify that features, numbers, steps, operations, components, parts, or combinations thereof described in the specification are present, and should not be interpreted as precluding the possibility that other features, numbers, steps, operations, components, parts, or combinations thereof are present or may be added.

Hereinafter, one or more example embodiments will be described in detail with reference to the accompanying drawings. Regardless of drawing reference numerals, identical or corresponding components will be assigned the same reference numerals, and redundant descriptions will be omitted.

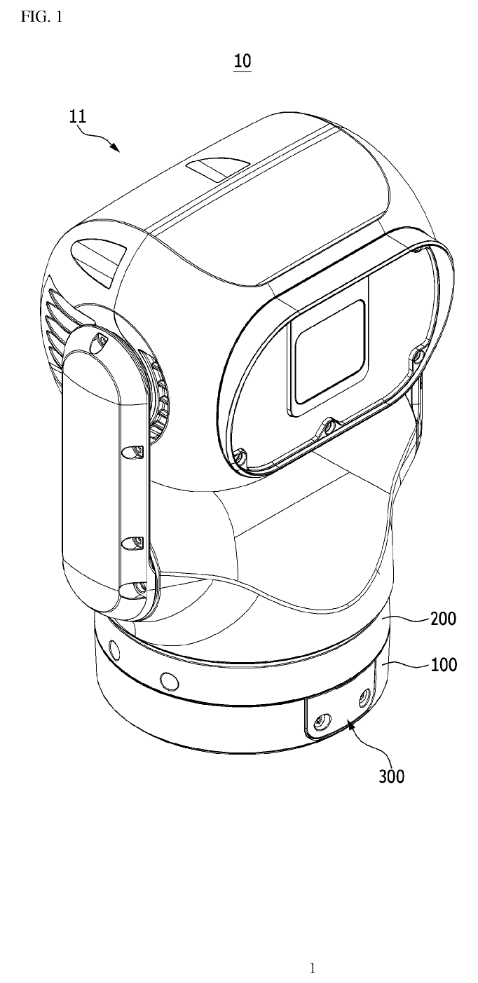

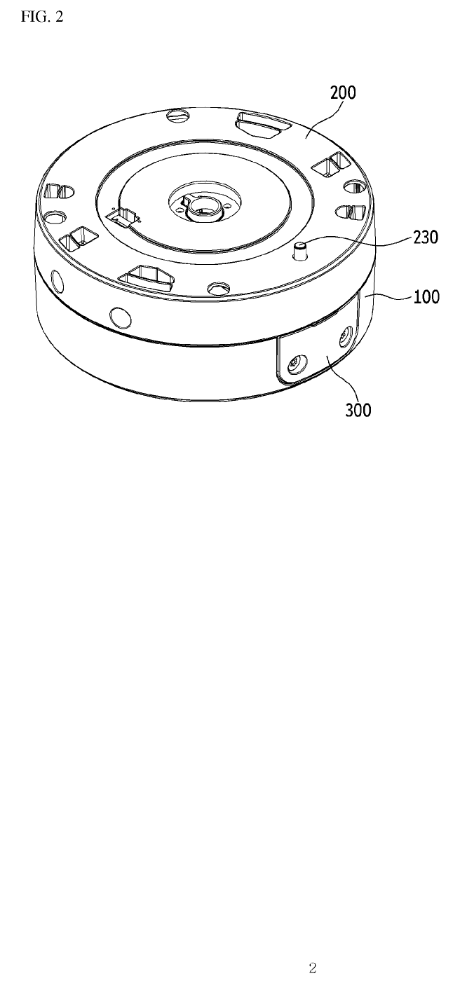

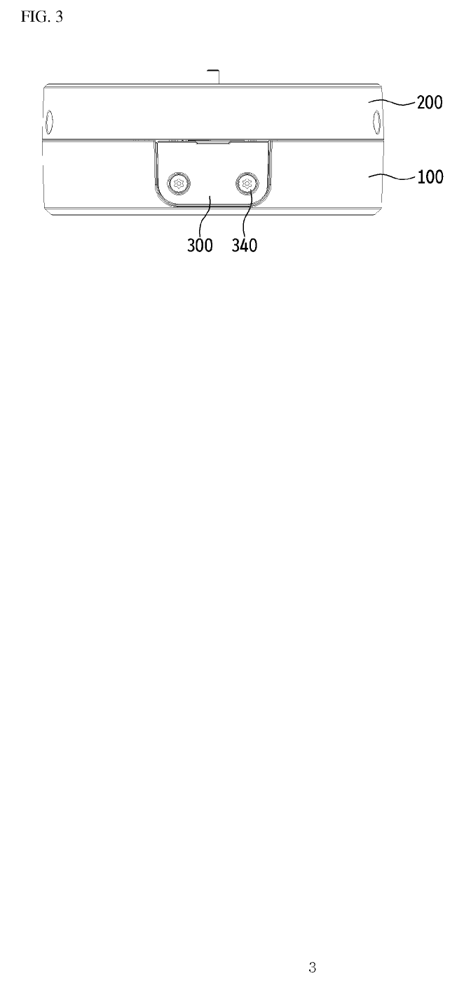

FIG. 1 is a perspective view illustrating a camera assembly, and FIGS. 2 and 3 are reference views illustrating a case for mounting a camera module of the camera assembly illustrated in FIG. 1 on an installation surface.

Referring to FIGS. 1 to 3, a camera assembly 10 may include a bottom case 100, a top case 200, and a switching module 300.

First, the bottom case 100 may be fixed on an installation surface. The bottom case 100 has a circular cross-section, but the shape is not limited thereto.

In addition, the top case 200 may have a camera module 11 mounted on one side, and may be detachably coupled to the bottom case 100 on the other side to form an accommodation space 101 therein. In a state in which the top case 200 is separated from the bottom case 100, the top case 200 and the camera module 11 may be fixed so as not to rotate, and in a state in which the top case 200 is coupled to the bottom case 100, the camera module 11 may rotate relative to the top case 200.

Further, the switching module (also referred to as “switching assembly,” “connector assembly,” “electrical connector assembly,” “connector carrier,” “connector carrier assembly,” etc.) 300 may be disposed so as to be movable into the accommodation space 101 through an opening (e.g., formed on a side surface of the bottom case 100 or the top case 200). For example, the switching module 300 may be configured to move into and out of the accommodation space 101 through the side surface of the bottom case 100, but the switching module 300 may also be formed as a structure provided in the top case 200. In particular, the switching module 300 may be configured to move between a stowed position, in which the switching module 300 is disposed in the accommodation space 101, and an ejected position, in which the switching module 300 is at least partially ejected from the accommodation space 101 and disposed at least partially outside of the bottom case 100 and the top case 200.

The camera module 11 is illustrated as being positioned above the bottom case 100 and the top case 200 with the bottom case 100 installed on a bottom surface, but the bottom case 100 may also be installed on a ceiling such that the camera module 11 is positioned therebelow.

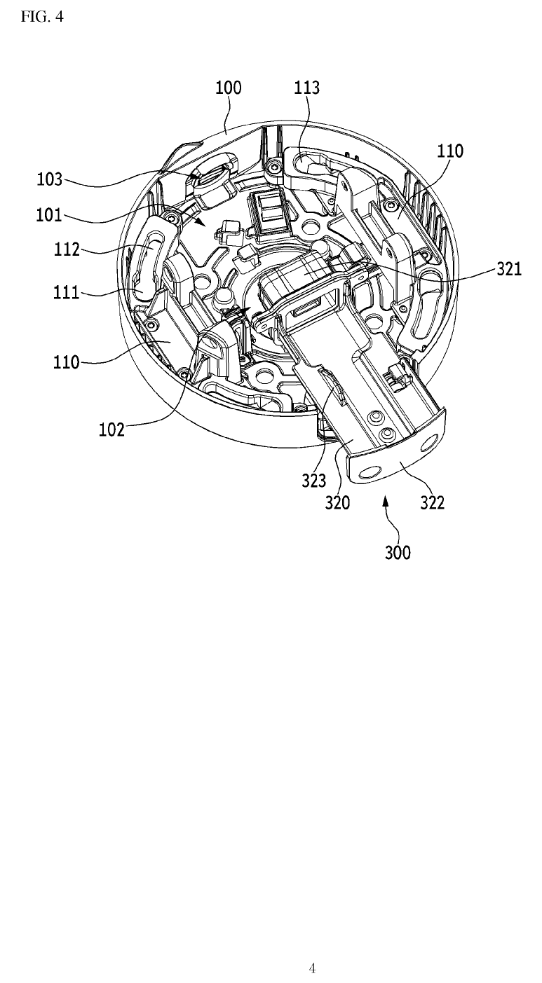

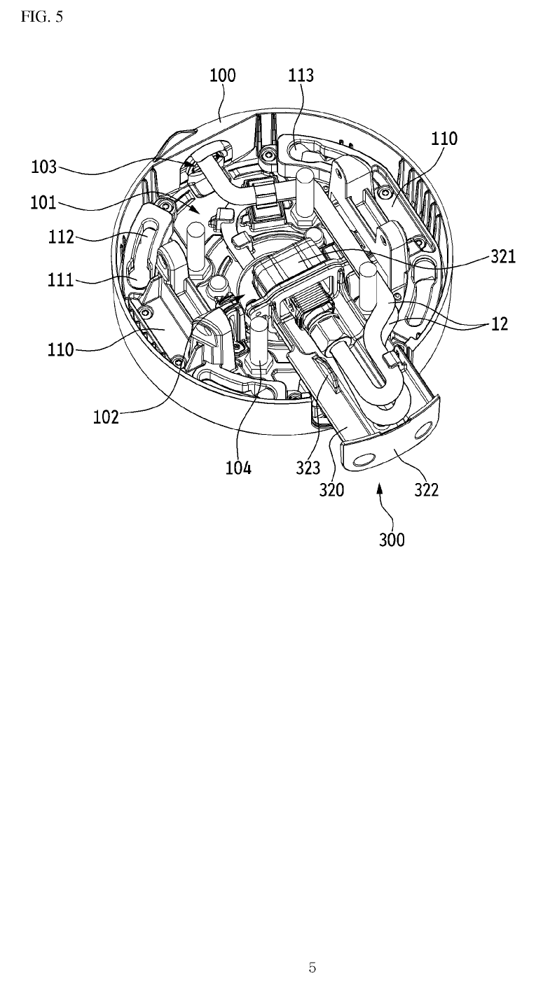

FIG. 4 is a perspective view illustrating a state in which the bottom case of the camera assembly illustrated in FIG. 2 is installed on the installation surface, and FIG. 5 is a reference view illustrating a state in which power and network cables are connected inside the bottom case of the camera assembly illustrated in FIG. 4.

Referring to FIGS. 4 and 5, in the camera assembly 10, the bottom case 100 may first be fixed to the installation surface.

A first inlet hole 102 may be formed in a bottom surface of the bottom case 100 facing the installation surface. For example, when a power or network cable 12 is disposed in a region where the installation surface and the bottom surface face each other, the power or network cable 12 may be connected to the accommodation space 101 inside the bottom case 100 through the first inlet hole 102.

In addition, a second inlet hole (e.g., opening) 103 may be formed on a side surface of the bottom case 100. For example, when the power or network cable 12 is not connected through the first inlet hole 102, the power or network cable 12 may be connected to the accommodation space 101 inside the bottom case 100 through the second inlet hole 103.

The first inlet hole 102 and the second inlet hole 103 may be selectively opened depending on a connection position of the power or network cable 12, or may be opened by removing a shielding member blocking each inlet hole.

Further, a fastening frame 110 may be provided along an edge of the accommodation space 101 inside the bottom case 100. The fastening frame 110 may be disposed to correspond to a position at which the top case 200 is fixed. For example, fastening frames 110 having the same shape are respectively provided on both inner sides of the bottom case 100.

The bottom case 100 may be fixed on the installation surface through a plurality of fasteners 104. Although not illustrated, when the bottom case 100 is detached from the installation surface, the bottom case 100 may be additionally connected through a wire (not illustrated) that supports the bottom case 100 so as to maintain a set distance from the installation surface in a detached state.

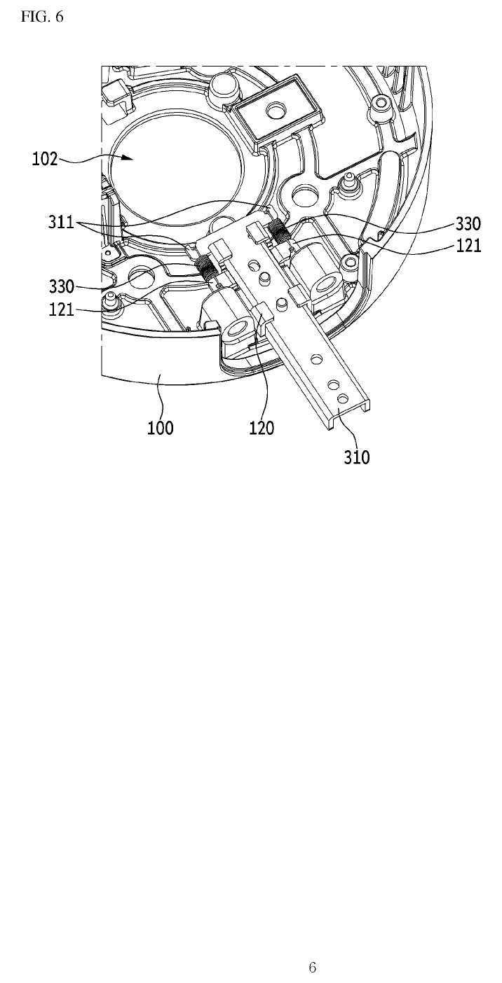

FIGS. 6 and 7 are perspective views illustrating the switching module of the camera assembly illustrated in FIG. 4.

Referring to FIGS. 6 and 7, the switching module 300 may include a movable frame 310, a network cover 320, first elastic members 330, a fastening member 340, and a second elastic member 350.

The movable frame 310 may be coupled with the network cover (also referred to as “connector housing,” “connector cover,” “cable cover,” “sliding cover,” “connector panel,” “access cover,” etc.) 320 so as to be slidable integrally. The movable frame 310 is disposed to be movable on a guide member 120 fixed to the bottom case 100, and may support sliding movement of the network cover 320 on the guide member 120.

At one end of the movable frame 310, first support ends 311 protruding on both sides in a direction perpendicular to a sliding direction of the movable frame 310 may be provided. When the movable frame 310 protrudes outward from the bottom case 100 to a maximum extent, inner sides of the first support ends 311 on both sides interfere with one end of the guide member 120, thereby limiting discharge (e.g., movement) of the movable frame 310.

Further, the guide member (also referred to as “guide rail,” “guide track,” “guide bracket,” etc.) 120 may be provided with second support ends 121 on both sides in parallel with the first support ends 311. The first support ends 311 and the second support ends 121 are disposed to maintain a predetermined distance, and the first elastic members 330 may be coupled on both sides to the first support ends 311 and the second support ends 121.

The first elastic members 330 may provide an elastic restoring force that pulls the first support ends 311 and the second support ends 121 toward each other. For example, each of the first elastic members 330 may be a spring (e.g., a compression spring, a tension spring, a torsion spring, etc.), a rubber band, a cord, etc. Accordingly, the movable frame 310 may be constantly provided with an elastic restoring force (e.g., biasing force) to be ejected (e.g., withdrawn, pushed, extended, discharged, etc.) outward from the accommodation space 101 on the guide member 120. That is, the network cover 320 may be provided with an elastic restoring force (e.g., biasing force) from the first elastic member 330 to be ejected outward from the bottom case 100. The first elastic member 330 may maintain a maximally stretched state in a state in which the network cover 320 is fully inserted into the accommodation space 101 (e.g., in the stowed position), and may push the network cover 320 outward from the accommodation space 101 (e.g., to the ejected position) simultaneously with release of a retention force (also referred to as “fixing force”) by the fastening member 340, thereby physically separating a first connector 321 from a second connector 13. The first elastic member 330 may store energy while being stretched when the network cover 320 is inserted into the accommodation space 101, and when the retention force of the fastening member 340 is released, may push the network cover 320 outward from the bottom case 100 with a force greater than a coupling force between the first connector 321 and the second connector 13. The first elastic member 330 may also be configured to store energy in a compressed state.

The network cover 320 may be fixed on the movable frame 310 so as to slide together with the movable frame 310. The first connector 321 may be provided on one side (e.g., in a first portion) of the network cover 320. The first connector 321 may be connected to the power or network cable 12 supplied from outside. Accordingly, when the network cover 320 slides, the first connector 321 may move inside the accommodation space 101. The second connector 13 connected to the camera module 11 may be provided at a lower portion of the top case 200 to be described later, and the first connector 321 and the second connector 13 may be arranged in parallel with a sliding direction of the network cover 320, such that when the network cover 320 slides into the accommodation space 101, the first connector 321 and the second connector 13 are connected to each other, and when the network cover 320 slides outward, the connection between the first connector 321 and the second connector 13 is released.

On the other side (e.g., in a second portion) of the network cover 320, a shielding surface 322 may be provided so as to provide the same side surface structure (e.g., share a same cylindrical surface, are flush with each other, form a continuous surface, etc.) as the side surface of the bottom case 100 when the network cover 320 is inserted into the accommodation space 101.

Further, the fastening member (also referred to as “fastener”) 340 may be provided on the other side of the network cover 320 so as to pass through the shielding surface 322 (e.g., through an opening of the shielding surface 322). The fastening member 340 may fix the network cover 320 and the bottom case 100 in a state in which the network cover 320 is inserted into the accommodation space 101, thereby preventing the network cover 320 from being ejected outward by the elastic restoring force of the first elastic member 330. The fastening member 340 may be, for example, a screw, a thumbscrew, a captive screw, a latch, a pin, a plunger pin, a spring plunger, a cam lock, a ball detent, a nail, a rivet, a bolt, a clip, adhesive, etc.

When the fastening member 340 releases the coupling between the network cover 320 and the bottom case 100, the network cover 320 may be ejected outward from the bottom case 100 by the elastic restoring force of the first elastic member 330. At this time, the fastening member 340 may not be separated from the network cover 320 and may be spaced apart from the network cover 320 outward by a predetermined distance.

For this purpose, the second elastic member 350 may be provided between the network cover 320 and the fastening member 340. For example, the second elastic member 350 may be a spring (e.g., a compression spring, a tension spring, a torsion spring, etc.), a rubber band, a cord, etc.

The second elastic member 350 may push the fastening member 340 outward from the other side of the network cover 320 when a retention force between the network cover 320 and the bottom case 100 is released, thereby facilitating separation of the network cover 320 and the bottom case 100.

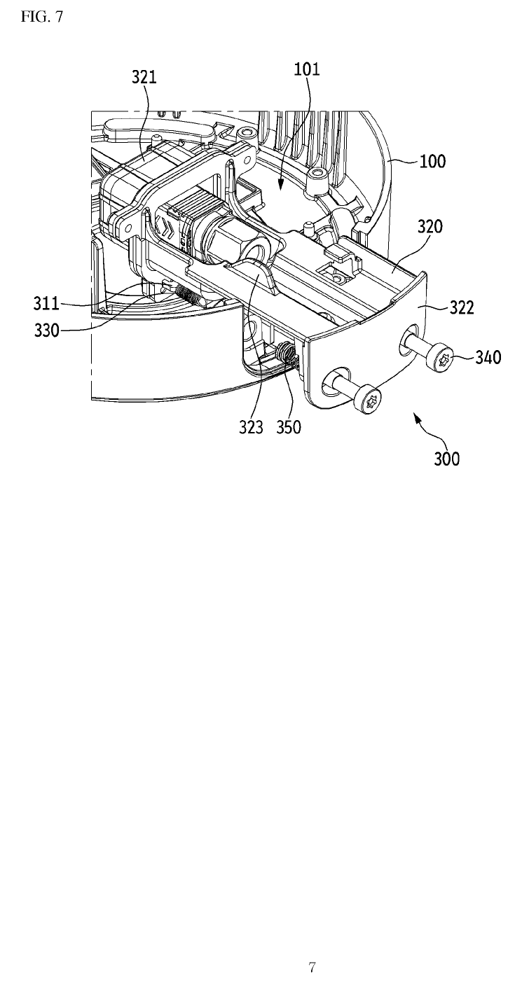

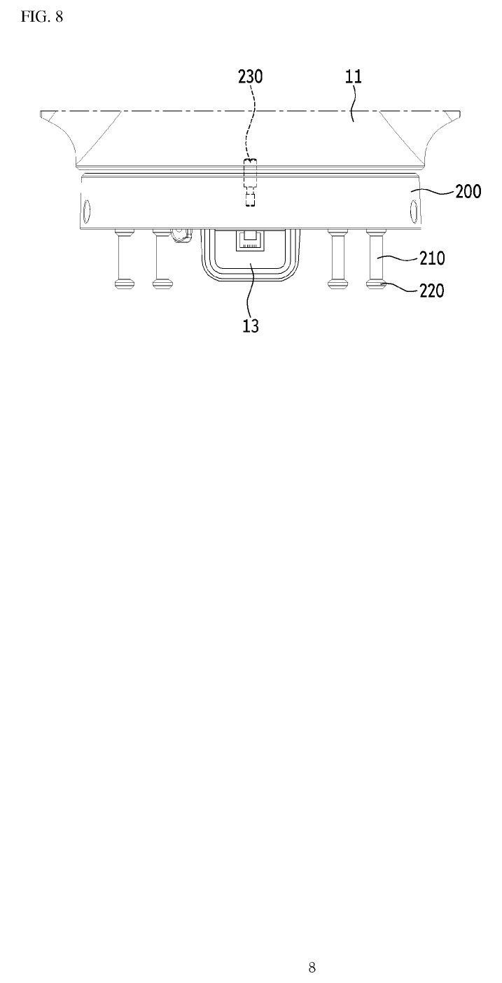

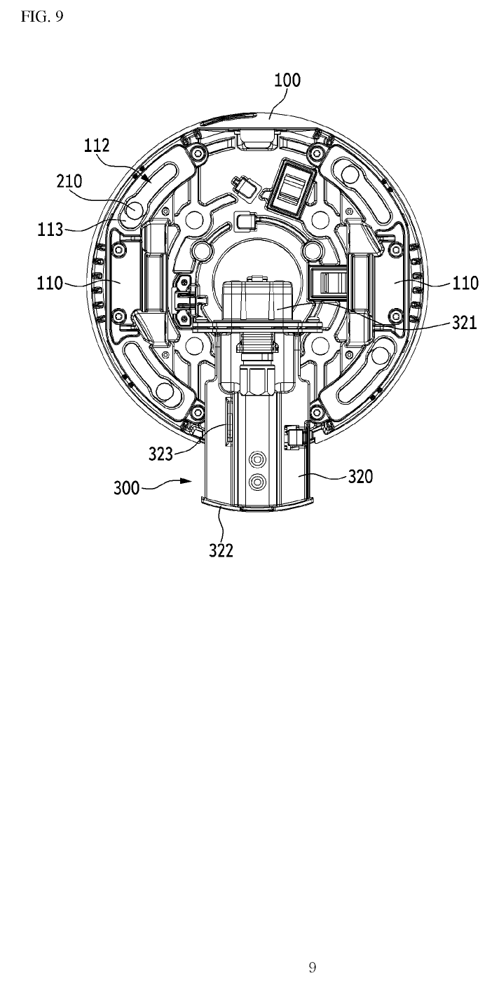

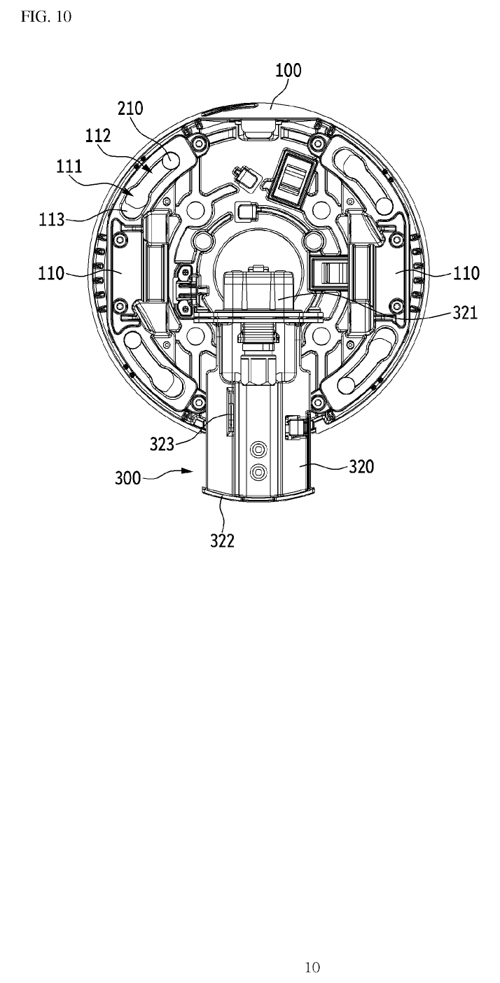

FIG. 8 is a reference view illustrating a lower portion of the camera module and the top case of the camera assembly illustrated in FIG. 2, and FIGS. 9 and 10 are reference views illustrating a state in which the top case and the bottom case of the camera assembly illustrated in FIG. 4 are coupled.

Referring to FIGS. 8 to 10, the top case 200 may include a plurality of guide shafts 210 protruding toward the fastening frame 110.

For example, a total of four guide shafts 210 may be provided and may be fixed by rotation after being inserted into the fastening frame 110. Each of the guide shafts 210 may be provided with a head portion 220 having a larger diameter or cross-sectional area at an end. The guide shafts 210 may be, for example, locking pins (e.g., also referred to as “twist-lock pins”) in a twist-lock mount, such as a keyhole slot fastener (e.g., with curved travel).

Correspondingly, the fastening frame 110 may be provided with fastening holes 111, fixing holes 112, and inclined surfaces 113.

The fastening holes 111 may be formed with a first width such that the head portions 220 are insertable. Each of the fastening holes 111 may be, for example, an entry portion of a keyhole slot (e.g., keyhole entry).

Further, the fixing holes 112 may be formed with a second width smaller than the first width and may be formed such that sides thereof communicate with the fastening holes 111. Each of the fixing holes 112 may be, for example, a retention portion (e.g., a neck portion, a slot portion, an engagement portion, etc.) of a keyhole slot. In this case, the head portions 220 may be inserted into the fastening frame 110 through the fastening holes 111 and then move toward the fixing holes 112 by rotation. At this time, since the width or diameter of each of the head portions 220 is larger than the second width (e.g., diameter) of each of the fixing holes 112, the guide shafts 210 may be prevented from being detached from the fixing holes 112.

Further, the inclined surfaces 113 may change a coupling direction toward the fixing holes 112 when the guide shafts 210 are inserted toward the fastening holes 111 from inner sides of the fastening holes 111. Conversely, when the guide shafts 210 are separated, if the head portions 220 rotate from the fixing holes 112 toward the fastening holes 111, the inclined surfaces 113 may change a detachment direction of the guide shafts 210 toward outer sides of the fastening holes 111.

When the guide shafts 210 move to the other sides of the fixing holes 112 in this manner, the network cover 320 may be allowed to slide into the accommodation space 101, and as the network cover 320 is inserted inward, the first connector 321 and the second connector 13 may be connected to each other. That is, the second connector 13 may be disposed at a fixed position inside the bottom case 100, and the first connector 321 may be fixed inside the network cover 320, such that as the network cover 320 slides along the guide member 120, the first connector 321 may be inserted into or detached from the second connector 13. Accordingly, a sliding direction of the network cover 320 and a direction in which the first connector 321 is inserted into the second connector 13 are formed to be parallel to each other, such that an operation in which the network cover 320 is completely inserted into the bottom case 100 and an operation in which the first connector 321 is completely inserted into the second connector 13 may be performed simultaneously.

When the top case 200 and the bottom case 100 are coupled, if the guide shafts 210 move to the other sides of the fixing holes 112, the switching module 300 may slide into the accommodation space 101.

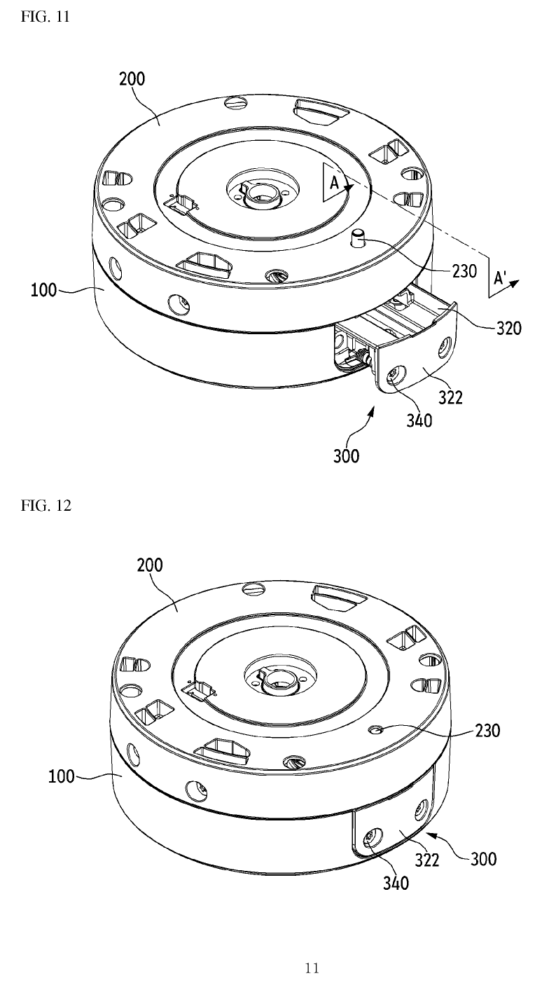

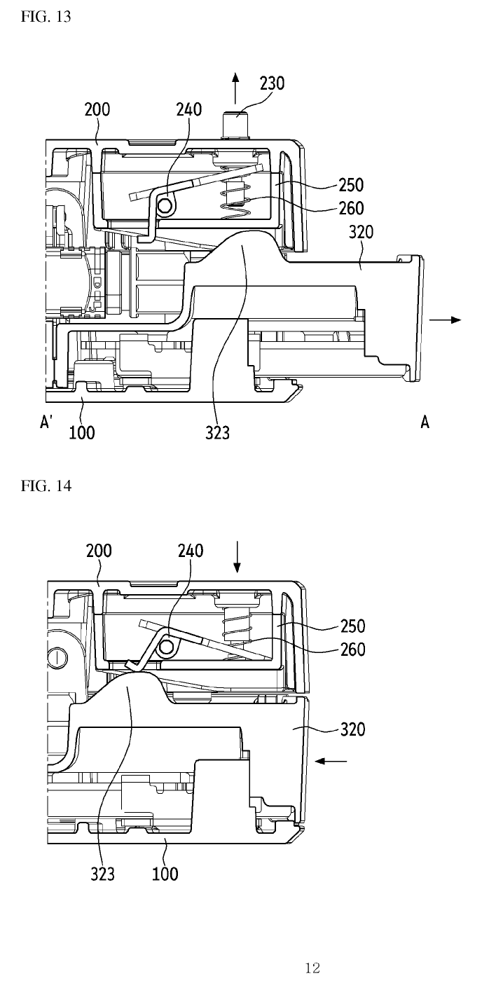

FIGS. 11 and 12 are reference views illustrating a rotation prevention member of the camera assembly illustrated in FIG. 2, and FIGS. 13 and 14 are cross-sectional views illustrating an operating state of the rotation prevention member of the camera assembly illustrated in FIG. 11.

Referring to FIGS. 11 to 14, the top case 200 may include a rotation prevention member 230, a pressing member 240, an inner case 250, and a third elastic member 260.

The rotation prevention member (also referred to as “rotation stop,” “rotation prevention pin,” “rotation lock,” etc.) 230 may protrude from an upper surface of the top case 200 toward the camera module 11, or may descend so as not to protrude from the upper surface of the top case 200.

Further, the pressing member (also referred to as “lever,” “pressing lever,” “actuating lever,” “cam follower,” etc.) 240 may be disposed to be rotatable inside the inner case 250. One side of the pressing member 240 may be disposed to interfere with the rotation prevention member 230, and the other side of the pressing member 240 may be exposed to outside the inner case 250 so as to interfere with a cam member (also referred to as “cam”) 323 provided on an upper portion of the network cover 320.

Further, the inner case 250 may be coupled inside the top case 200 so as to cover the rotation prevention member 230 and the pressing member 240.

The third elastic member 260 may provide an elastic restoring force (e.g., biasing force) in a direction in which the rotation prevention member 230 protrudes from the upper surface of the top case 200 at an inner bottom surface of the inner case 250. For example, the third elastic member 260 may be a spring (e.g., a compression spring, a tension spring, a torsion spring, etc.), a rubber band, a cord, etc. Alternatively, the third elastic member 260 may provide an elastic restoring force (e.g., biasing force) to the pressing member 240 so as to allow the rotation prevention member 230 to rise together therewith.

At this time, the network cover 320 may be provided with the cam member 323 so as to interfere with the other side of the pressing member 240 along a direction in which the network cover 320 enters and exits the accommodation space 101. The cam member 323 may be, for example, a linear cam or a translation cam. For example, as the network cover 320 is inserted into the accommodation space 101, the cam member 323 may rotate the pressing member 240 (e.g., cause the pressing member 240 to rotate) in one direction to lower the rotation prevention member 230, and conversely, as the network cover 320 is ejected to outside the accommodation space 101 and a force for rotating the pressing member 240 in one direction by the cam member 323 is released, the third elastic member 260 may raise the rotation prevention member 230 and the pressing member 240 to cause the rotation prevention member 230 to protrude from the top case 200.

Accordingly, when the top case 200 and the camera module 11 are coupled to the bottom case 100 in a state in which the top case 200 and the camera module 11 are coupled to each other, relative rotation between the top case 200 and the camera module 11 may be prevented, thereby facilitating coupling of the top case 200 and the bottom case 100. Further, after the top case 200 and the bottom case 100 are coupled, when the network cover 320 is inserted into the accommodation space 101, the camera module 11 may rotate on the top case 200.

According to an aspect of the present disclosure, a camera assembly includes: a bottom case fixedly installed on an installation surface; a top case having a camera module mounted on one side thereof, and detachably coupled on the bottom case on the other side to form an accommodation space therein; and a switching module disposed to be movable into the accommodation space through a side surface of the bottom case or the top case, wherein: when the switching module is inserted into the accommodation space, power and a network are connected to the camera module; and when the switching module is discharged from the accommodation space to the outside, the connection of the power and the network to the camera module is released.

The switching module may include: a movable frame disposed to be slidable on a guide member installed on the bottom case; and a network cover mounted on the movable frame, having a first connector connected to a power or network cable provided on one side, and moving the first connector to be connected to a second connector connected to the camera module while sliding together with the movable frame.

The switching module may further include a first elastic member connected between the movable frame and the guide member and providing an elastic restoring force such that the movable frame is discharged outward from the accommodation space.

The switching module may further include: a fastening member provided on the other side of the network cover and selectively fixing the network cover and the bottom case in a state in which the network cover is inserted into the accommodation space; and a second elastic member spacing the fastening member outward by a predetermined distance from the other side of the network cover when a fixing force between the network cover and the bottom case is released.

At a moment when a fixing force of the fastening member is released, connection between the first connector and the second connector may be released by an elastic restoring force of the first elastic member.

The top case may include: a rotation prevention member selectively protruding from an upper surface to prevent rotation of the camera module; a pressing member disposed to be rotatable inside the top case according to entry and exit of the network cover to push or pull the rotation prevention member to outside the top case; an inner case provided to cover a lower portion of the rotation prevention member and the pressing member inside the top case; and a third elastic member pressing the pressing member and the rotation prevention member from an inner bottom surface of the inner case such that the rotation prevention member protrudes from the upper surface of the top case.

The network cover may include a cam member that rotates the pressing member in one direction while being inserted into the accommodation space to lower the rotation prevention member, and, when the network cover is discharged to outside the accommodation space and a force for rotating the pressing member in one direction is released, raises the rotation prevention member and the pressing member by the third elastic member to cause the rotation prevention member to protrude on the top case.

The power or network cable may be connected through one inlet hole selected from among a first inlet hole formed in a bottom surface of the bottom case facing the installation surface and a second inlet hole formed in a side surface adjacent to the installation surface.

The top case may include a plurality of guide shafts protruding toward the accommodation space and each having a head portion formed with a larger cross-sectional area at a protruding end.

The bottom case may include a fastening frame installed in the accommodation space and fixing the top case and the bottom case while the guide shafts are inserted and then rotated along a circumferential direction.

The fastening frame may include: a fastening hole having a first width such that the head portion is insertable; a fixing hole having a second width smaller than the first width and communicating with the fastening hole on one side; an inclined surface changing a coupling direction of the head portion inserted into the fastening hole toward the fixing hole, thereby fixing each of the guide shafts at the fixing hole.

If each of the guide shafts rotates to the other side of the fixing hole when the top case and the bottom case are coupled, the switching module may be disposed to be slidable into the accommodation space.

The network cover may include a shielding surface providing the same side surface structure as a side surface of the bottom case in a state in which the network cover is inserted into the accommodation space.

When the network cover slides inward in the accommodation space such that the shielding surface and the side surface of the bottom case form a same plane, the first connector and the second connector may be connected.

The first connector and the second connector may be disposed in parallel with a sliding direction of the network cover, such that power and network signals are simultaneously connected or disconnected according to sliding movement of the network cover.

The first elastic member may maintain a maximally stretched state in a state in which the network cover is fully inserted into the accommodation space, and may push the network cover outward from the accommodation space simultaneously with release of a fixing force by the fastening member, thereby physically separating the first connector from the second connector.

When the switching module is inserted into the accommodation space, rotation of the camera module on the top case may be enabled, and when the switching module is discharged to outside the accommodation space, rotation of the camera module on the top case may be restricted.

The second connector may be disposed at a fixed position inside the bottom case, and the first connector may be fixed inside the network cover, such that the first connector is inserted into or detached from the second connector as the network cover slides along the guide member.

The first elastic member may store energy while being compressed or stretched when the network cover is inserted into the accommodation space, and may push the network cover outward from the bottom case with a force greater than a coupling force between the first connector and the second connector when a fixing force of the fastening member is released.

A sliding direction of the network cover and a direction in which the first connector is inserted into the second connector may be formed to be parallel to each other, such that an operation in which the network cover is fully inserted into the bottom case and an operation in which the first connector is fully inserted into the second connector are performed simultaneously.

According to the camera assembly of the present disclosure, the following effects may be provided.

First, since power and network cables are connected to a switching module when a bottom case is mounted on an installation surface, there is no need to connect a camera module to the power and network cables after installation of the bottom case.

Second, coupling of the bottom case and a top case is facilitated in a state in which the camera module and the top case are coupled.

Third, power and network connections can be released without separating the camera module.

It should be noted that the effects of the present disclosure are not limited to those described above, and other effects of the present disclosure will be apparent from the following description.

According to the camera assembly according to the present disclosure, when the bottom case is mounted on the installation surface, power and network cables are connected to the switching module, such that there is no need to connect the camera module and the power and network cables after installation of the bottom case. Additionally, coupling of the bottom case and the top case may be facilitated in a state in which the camera module and the top case are coupled. Further, power and network connections may be released without separating the camera module.

While the technical spirit of the present disclosure has been illustrated and described with reference to example embodiment(s) above, the present disclosure is not limited to these example embodiment(s), and various modifications may be implemented without departing from the scope of the present disclosure. Therefore, such modifications should also be regarded as being included within the scope of the present disclosure, and the scope of the present disclosure should be determined by the claims described below.

What is claimed is:

1. A camera assembly comprising:
a bottom case configured to attach to an installation surface;
a top case having a first side detachably coupled to the bottom case to form an accommodation space within the top case and the bottom case;
a camera module mounted on a second side of the top case; and
a connector carrier assembly comprising a power cable and a network cable, wherein the connector carrier assembly is configured to be movable, through an opening formed on a side surface of at least one of the bottom case or the top case, between a stowed position, in which the connector carrier assembly is disposed in the accommodation space, and an ejected position, in which the connector carrier assembly is at least partially ejected from the accommodation space, and wherein the power cable and the network cable of the connector carrier assembly are configured to be:
based on the connector carrier assembly being in the stowed position, connected to the camera module; and
based on the connector carrier assembly being in the ejected position, disconnected from the camera module.

2. The camera assembly of claim 1, wherein the connector carrier assembly comprises:
a movable frame disposed to be slidable on a guide rail installed on the bottom case; and
a connector housing mounted on the movable frame and having a first connector connected to the power cable or the network cable provided on a first position of the connector housing, wherein the connector housing is configured to move the first connector to be connected to a second connector that is connected to the camera module.

3. The camera assembly of claim 2, wherein the connector carrier assembly further comprises a first spring connected between the movable frame and the guide rail and providing an elastic restoring force such that the movable frame is ejected outward from the accommodation space.

4. The camera assembly of claim 3, wherein the connector carrier assembly further comprises:
a fastener provided on a second side of the connector housing and configured to lock the connector housing and the bottom case in the stowed position; and
a second spring configured to push the fastener outward by a predetermined distance from the second side of the connector housing based on a retention force between the connector housing and the bottom case being released.

5. The camera assembly of claim 4, wherein, at a moment when the retention force of the fastener is released, connection between the first connector and the second connector is released by the elastic restoring force of the first spring.

6. The camera assembly of claim 2, wherein the top case comprises:
a rotation stop protruding from an upper surface to prevent rotation of the camera module;
a lever disposed to be, according to entry or exit of the connector housing, rotatable inside the top case to push the rotation stop out of the top case or pull the rotation stop into the top case;
an inner case provided to cover a lower portion of the rotation stop and the lever inside the top case; and
a third spring configured to push the lever and the rotation stop from an inner bottom surface of the inner case such that the rotation stop protrudes from the upper surface of the top case.

7. The camera assembly of claim 6, wherein the connector housing comprises a cam that is configured to:
cause the lever to rotate in a first direction, while the connector housing is being inserted into the accommodation space, to lower the rotation stop, and
based on the connector housing being ejected out of the accommodation space and a force for rotating the lever in the first direction being released, raise the rotation stop and the lever by the third spring to cause the rotation stop to protrude from the top case.

8. The camera assembly of claim 2, wherein the power cable or the network cable is connected through one inlet hole selected from among: a first inlet hole formed on a bottom surface of the bottom case facing the installation surface, and a second inlet hole formed on a side surface adjacent to the installation surface.

9. The camera assembly of claim 2, wherein the top case comprises a plurality of locking pins protruding toward the accommodation space, and wherein each locking pin, of the plurality of locking pins, has a head portion formed with a larger cross-sectional area at a protruding end than at an opposite end of the locking pin.

10. The camera assembly of claim 9, wherein the bottom case comprises a fastening frame installed in the accommodation space and configured to keep the top case fastened to the bottom case while the plurality of locking pins are inserted and rotated along a circumferential direction.

11. The camera assembly of claim 10, wherein the fastening frame comprises:
a plurality of keyhole slots, wherein each keyhole slot of the plurality of keyhole slots comprises:
an entry portion having a diameter such that the head portion of a corresponding locking pin, of the plurality of locking pins, is insertable through the entry portion;
a retention portion having a width that is less than the diameter of the entry portion and communicating with the entry portion on a first side of the retention portion; and
an inclined surface configured to change a coupling direction of the head portion, of the corresponding locking pin, inserted into the entry portion toward the retention portion, thereby securing a corresponding locking pin of the plurality of locking pins at the retention portion.

12. The camera assembly of claim 11, wherein the connector carrier assembly is configured to, based on the top case and the bottom case being coupled and each of the plurality of locking pins rotating to a second side of the retention portion of a corresponding keyhole slot, slide into the accommodation space.

13. The camera assembly of claim 2, wherein the connector housing comprises a shielding surface configured to, based on the connector housing being in the stowed position, have a same side surface structure as a side surface of the bottom case.

14. The camera assembly of claim 13, wherein the connector housing is configured to slide inward into the accommodation space, to be in the stowed position, such that the shielding surface and the side surface of the bottom case are flush with each other, and the first connector and the second connector are connected to each other.

15. The camera assembly of claim 2, wherein the first connector and the second connector are disposed in parallel with a sliding direction of the connector housing, such that power cable and the network cable are simultaneously connected to the camera module or disconnected from the camera module according to a sliding movement of the connector housing.

16. The camera assembly of claim 4, wherein the first spring is configured to:
maintain a maximally stretched state based on the connector housing being in the stowed position, or
based on the retention force being released, push the connector housing to the ejected position and physically separate the first connector from the second connector.

17. The camera assembly of claim 7, wherein, based on the connector carrier assembly being in the stowed position, rotation of the camera module on the top case is enabled, and
wherein, based on the connector carrier assembly being in the ejected position, rotation of the camera module on the top case is restricted.

18. The camera assembly of claim 2, wherein the second connector is disposed at a fixed position inside the bottom case, and wherein the first connector is fixed inside the connector housing, such that the first connector is inserted into or detached from the second connector as the connector housing slides along the guide rail.

19. The camera assembly of claim 4, wherein the first spring is configured to:
store energy based on the connector housing being in the stowed position; and
push the connector housing outward from the bottom case with a force greater than a coupling force between the first connector and the second connector based on the retention force of the fastener being released.

20. The camera assembly of claim 15, wherein the sliding direction of the connector housing is parallel to a direction in which the first connector is inserted into the second connector, and wherein, based on the connector housing being in the stowed position, the first connector is fully inserted into the second connector.
